(19) United States
(12) Patent Application Publication
(10) Pub. No.: US 2026/0271450 A1
(43) Pub. Date: Sep. 10, 2026

(54) METHOD FOR PROCESSING AN ARRANGEMENT HAVING µLEDS AND ARRANGEMENT

(71) Applicant: ams-OSRAM International GmbH, Regensburg (DE)

(72) Inventor: Robert Schulz, Schierling (DE)

(21) Appl. No.: 19/164,130

(22) PCT Filed: Mar. 17, 2023
(86) PCT No.: PCT/EP2023/056939

§ 371 Date: Sep. 10, 2025

(51) Int. Cl. H10H 29/01; H10H 29/80; H10H 29/85; H10P 14/69; H10P 34/42; H10P 76/40

(52) U.S. Cl. CPC H10H 29/032; H10H 29/011; H10H 29/034; H10H 29/8323; H10H 29/8508; H10P 14/69; H10P 34/42; H10P 76/40

(57) ABSTRACT

In an embodiment a method for processing an arrangement includes providing a plurality of vertical optoelectronic components onto a carrier substrate, the plurality of vertical optoelectronic components including a contact area on a top surface opposite the carrier substrate, embedding the plurality of vertical optoelectronic components into a photoactive material, the photoactive material covering spaces between adjacent optoelectronic components of the plurality of vertical optoelectronic components and the top surface, and illuminating portions of the photoactive material above the top surface comprising at least partially the contact area, and developing the photoactive material thereby removing portions of the photoactive material such that a portion of the top surface comprising at least partially the contact area is exposed and a portion of an inactivated photoactive material extending onto the top surface includes a curvature and such that a thickness of the photoactive material partially increases towards an exposed contact area.

### CROSS-REFERENCE TO RELATED APPLICATIONS

This patent application is a national phase filing under section 371 of PCT/EP2023/056939, filed Mar. 17, 2023, which is incorporated herein by reference in its entirety.

### TECHNICAL FIELD

The present invention concerns a method for processing an optoelectronic component and in particular a μLEDs, as well as an optoelectronic arrangement including a plurality of μLEDs.

### BACKGROUND

The testing of several μLEDs at once and at various stages of its manufacturing process is necessary to avoid larger batches of broken components and to increase the yield during production. While it is possible to conduct some tests on directly wafer level, it is also common to provide dedicated test arrangements, referred to as test vehicles.

For preparing such test vehicles, a plurality of μLEDs is taken from the production wafer and placed on a respective carrier test substrate. The plurality of μLEDs is then processed further to implement the test vehicle, which is subsequently used for a variety of electrical and optical tests. However, the preparation and implementation of such testing vehicles, being an arrangement with a plurality of μLEDs is error-prone.

Particularly, the step of spinning dielectric material as SOG (spin-on-glass) onto the carrier and the respective μLEDs creates a step around the μLEDs. Any conductive layer like ITO deposited and sputtered upon the SOG material tends to crack due to that step around the μLEDs. In particular, subsequent stress tests during the test procedure with the arrangement undergoing real life scenarios can lead to breakages in the conductive layer material. Those issues do not necessarily only concern test vehicles, but also generally arrangements having a plurality of μLEDs like displays, light projectors and the like.

In conventional techniques, the surface of the μLEDs is open by a dry etching process removing the SOG material on the top surface. However, due to the various tolerances like thickness of the μLEDs, a small inclination when placing the μLEDs on the carrier substrate, solder thickness and other aspects result that the top surfaces of a plurality of μLEDs are usually uneven. The etching process to remove the SOG material exposing all surfaces will therefore etch SOG material between the μLEDs, thereby rendering a defined and reproducible process for the deposition of a conductive material for testing and other purposes difficult.

### SUMMARY

Embodiments provide an improved arrangement with a plurality of μLEDs, resulting in a less error-prone structure with higher reproducibility.

Embodiments provide amending the process steps for producing and manufacturing an arrangement with a plurality of μLEDs by embedding the plurality of μLEDs with a planarized material, that is photoactive, and can therefore easily be structured without a dry etching process. Consequently, areas of such photoactive material can be developed using a photo mask layer or using a direct laser imaging device, thereby subsequently exposing contact surfaces for contacting the plurality of μLEDs.

The newly proposed steps do not require a back etching or a mechanical grinding process to remove the spin-on-glass material, but only a much simpler removal of a portion of the photo active material. The photo active polymerization material remains on the arrangement embedding the optoelectronic components and μLEDs, respectively. This reduces the risk of damaging the respective μLEDs during processing due to the above-mentioned tolerances and allows an improved process control. In addition, several steps used in conventional processing techniques can be skipped, thereby providing a faster manufacturing process, which is particularly suitable for arrangements used for test purposes.

Embodiments provide a method for processing an arrangement with a plurality of optoelectronic components and in particular μLEDs. Such a method comprises the step of providing a plurality of vertical components and in particular vertical μLEDs on a carrier substrate. The vertical optoelectronic components each comprise a contact area on the top surface opposite the carrier substrate.

In this regard, the term “vertical optoelectronic component” refers to an optoelectronic component that comprises two contact areas on opposing sides. In the proposed principle, such vertical optoelectronic components are arranged on the carrier substrate and with their respective bottom contact areas being connected to respective contact areas on the carrier substrate. The opposite contact area is arranged on the top surface of the optoelectronic component.

The expression “μLED” refers to an optoelectronic component, which can be a volume or a surface emitter, that comprise a length or width of less than 70 μm and down a few micrometres. Typical μLEDs comprise a length of approximately 4 μm to 20 μm, for example 15 μm, 10 μm or 8 μm. These μLEDs are usually implemented as a vertical optoelectronic components due to their sizes.

The plurality of vertical optoelectronic components is embedded into the photo active material in accordance with the proposed principle. The photo active material fills the space between the adjacent vertical optoelectronic components as well as the top surface of such components. The material forms a more or less planar surface on the carrier substrate and the components, whereas the optoelectronic components can lead to small curved protrusions in the shape of small hills on the plane of the photo active material. Hence, the photo active material may not be total even, but slightly uneven, wherein the roughness may be less than 1 μm or less than 0,5 μm in most instances, and certainly less than the height of the vertical optoelectronic components.

Portions of the photo active material positioned above the top surface containing at least partially the contact area of the respective optoelectronic components are then illuminated and therefore developed. The developed portions can then be removed leaving the undeveloped portions behind. As an alternative, it is also possible to reverse this step, that is for example, illuminate and develop the photo active material not positioned above the top surface containing at least partially the contact area of the respective optoelectronic components and then remove the un-developed portions above the top surface.

In both cases, the subsequent removal will expose a portion of the top surface containing at least partially the contact area.

Then, a conductive transparent layer is provided onto the remaining photo active material as well as the exposed portions of the top surface of the vertical optoelectronic components to electrically contact the contact area of the respective optoelectronic components.

As indicated, the proposed principle protects the optoelectronic components from potential damages by embedding the components in the photo active material, whereas the respective top surface can be exposed and subsequently contacted without additional etching steps. In addition, potential edges between the optoelectronic components and spin-on-glass material due to different etching rates used in conventional techniques are reduced or completely avoided. However, advantages like very precise positioning of photo mask layers or direct laser imaging process can be maintained.

In some further aspects, a structured mask layer is provided onto the photo active material such that a portion of the top surface is exposed containing at least partially the contact area. In this regard, the structured mask layer may comprise a plurality of transparent elements, for example holes or lenses and the like. Those transparent elements are positioned above the portion of the top surface containing at least partially the contact area. The photo active material above those portions is subsequently illuminated to be removed in a later more simplified washing step without the need for etching the photo active material.

A direct laser imaging device can be used instead of a structured photo mask layer. Here, the position of the top layer surface of the plurality of optoelectronic components on the carrier substrate are first obtained. After obtaining such positions, the direct laser imaging device is used to illuminate the portions of the photo active material above the top surface containing at least partially the contact area of the vertical optoelectronic components. This particular process has the benefit that the position of the respective top surface of the plurality of optoelectronic components can be obtained after those components are placed on the carrier substrate, but prior to embedding those in the photo active material. Hence, tolerances or inclinations during the positioning or arrangement process of the plurality of optoelectronic components on the carrier substrate can be compensated.

In some further aspects, the step of developing the photo active material comprises the step of removing portions that have been illuminated, such that non-illuminated portions of the photo active layer remain on the carrier substrate. However, this particular step can also be reversed such that the step of developing the protective material comprises the step of removing portions that have not been illuminated such that illuminated portions of the photo active layer remain on the carrier substrate.

The latter step is apparently useful in cases, in which the carrier substrate within the plurality of optoelectronic components is further processed to implement a display or any other arrangement and in which the photo active material remains on the carrier substrate under normal operation of such arrangement. It may be useful in such circumstances to protective photo active material from oxygen or other degrading substances.

Some further aspects relate to the step of providing a structured mask layer. Such step may comprise providing a structured mask layer comprising a plurality of transparent portions like holes, lenses and such. The structured mask layer is arranged above the photo active layer material, such that each transparent portion or all of the plurality of transparent portions are positioned above respective portions of the top surface containing at least partially the contact area. However, the transparent portions in the structured mask layer are slightly smaller than the area of the top surface. As a result, during the subsequent illumination step, the photo active layer on the top surface is not completely illuminated but only a portion thereof, leaving the material on the circumferential edges un-developed.

Consequently, after the step of removing developed portions, a small section of the photo active material may remain on the circumferential edges of the top surface of the respective optoelectronic components. In this regard, the plurality of transparent portions may comprise the shape of a circle or a rectangle. Alternatively, an oval shape or a polygon shape for the plurality of transparent portions can also be used. After removing the illuminated photo active, the recess formed thereon exposing the contact area may comprise the same shape.

Some steps concern the step of embedding the plurality of vertical optoelectronic components into the photo active material. In some aspects, the photo active material may be sputtered onto the carrier substrate and the optoelectronic components thereby covering the optoelectronic components and the top surface thereof. Alternatively, the photo active material can be deposited onto the carrier substrate and the plurality of optoelectronic components by spinning.

As a further alternative, the photo active material may be dispensed onto the carrier substrate and in particularly between the spaces of adjacent optoelectronic components of the plurality of vertical optoelectronic components. In some instances, sections of the photo active material may also be dispensed onto the top surface of some of the plurality of vertical optoelectronic components. In yet another alternative, the photo active material may be jetted onto the carrier substrate and in particular between spaces of adjacent optoelectronic components. The photo active material may also be jetted onto the top surface of some or all of the plurality of vertical optoelectronic components.

In this regard, the step of developing may comprise etching the illuminated or developed portions of the photo active material. Alternatively, the non-illuminated portions (corresponding to the undeveloped portions) of the photo active material can be etched. However, such etching process is different from an etching process of the spin-on-glass material as in conventional techniques and resemble a simple removal of the photo active material using solvents suitable for removing the material. These solvents are usually not aggressive and do not interfere or damage the optoelectronic components or the inactivated portions of the photo active material.

A heated treatment may be conducted after disposing of the photo active material, prior or after the step of developing the material. For example, the photo active material remaining after developing and the removal process can be baked to further improve stabilization and avoid delamination in subsequent steps. In this regard, the thermal expansion coefficient CTE is selected such that it is similar to the surrounding material for the temperature ranges used during operation of the arrangement.

The conductive transparent layer may comprise ITO and can be sputtered onto the remaining photo active material and the top surface of the optoelectronic components, such that it extends over the edge between the photo active material and the exposed contact areas of the top surface. In this regard, the thickness of the conductive transparent layer or simply the amount of the sputtered material is large enough that the thickness on the exposed contact areas of the top surface connects smoothly with the conductive transparent material on the photo active layer surrounding the exposed contact areas.

Another aspect is related to an arrangement having a plurality of optoelectronic components. The arrangement comprises a carrier substrate comprising a plurality of contact leads. A plurality of vertical optoelectronic components and in particular μLEDs are arranged on the carrier substrate and particularly on the plurality of contact leads. The arrangement is done in such way that the first contact area of each of the plurality of vertical optoelectronic components connects a respective contact lead on the carrier substrate. Furthermore, each of the plurality of vertical optoelectronic components comprises a second contact area, which is opposite to the first contact area.

In accordance with the proposed principle, a non-conductive inactivated photo active material is arranged on the carrier substrate embedding the plurality of vertical optoelectronic components therein. A portion of the inactivated photo active material extends onto the top surface of the respective plurality of vertical optoelectronic components, leaving at least a portion of the second contact area exposed. For example, the portions of the top surface covered by the inactivated photo active material may comprise the circumferential edge portions of the plurality of vertical optoelectronic components. A conductive transparent layer covers the inactivated photo active material as well as the exposed contact area of the plurality of vertical optoelectronic components, thereby providing an electric contact.

Since the thickness of the inactivated photo active material extending onto the top surface is significantly smaller, the step between the exposed contact area and the photo active material is thin enough such that the transparent conductive layer forms a stable and very well defined and controllable contact. More particularly, such step is not arranged along the sidewalls of the optoelectronic components as in conventional techniques, avoiding the risk of breaking or rupturing of the conductive transparent material due to thermal stress. In some instances, the thickness of such step may be in the range of a few nm to about 500 nm, and in any case less than 1 μm. Hence, in some instances, the transparent conductive material may comprise a thickness that is larger than a step of the photo active material extending above the top surface level.

In some aspects of the exposed area of the top surface may comprise the shape of a circle, a rectangle, a polygon or an oval.

Some aspects concern the shape and structure of the portion of the inactivated photo active material extending above the top surfaces of the vertical optoelectronic components. As already mentioned, the inactive photo active material is extended on the top surface along the circumferential edges of the respective optoelectronic component. In some aspects, the surface of the inactivated photo active material may comprise a curvature such that the thickness of the photo active material is partially increased towards the exposed contact area. Hence, the thickness of the photo active material may become larger towards the centre of the respective optoelectronic component.

This characteristics is adjusted and to some extent controlled by the amount of material deposited, but also by the deposition technique. For example, spinning the material the photo active material can result in a different surface shape than when the photoactive material is sputtered, thereby generating protrusions and elevations due to the obstacles provided by the optoelectronic components. As a result, the portion of the inactivated photo active material extending onto the top surface may comprise a curvature with an increasing slope towards the exposed contact areas when viewed in a cut view. However any roughness of the surface of the photoactive material (i.e. distance between the lowest and the highest portion is probably less than 1 μm and particularly less than 500 nm.

### BRIEF DESCRIPTION OF THE DRAWINGS

Further aspects and embodiments in accordance with the proposed principle will become apparent in relation to the various embodiments and examples described in detail in connection with the accompanying drawings in which

FIGS. 1A to 1D show a method for processing an arrangement;

FIGS. 2A to 2D illustrate a method for processing an arrangement in accordance with some aspects of the proposed principle;

FIG. 3 shows an alternative method steps during processing an arrangement in accordance with some aspects of the proposed principle;

FIGS. 4A to 4C illustrate a top view of an optoelectronic component during processing an arrangement in accordance with some aspects of the proposed principle; and

FIG. 5 illustrates an arrangement with an optoelectronic component embedded in such material.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

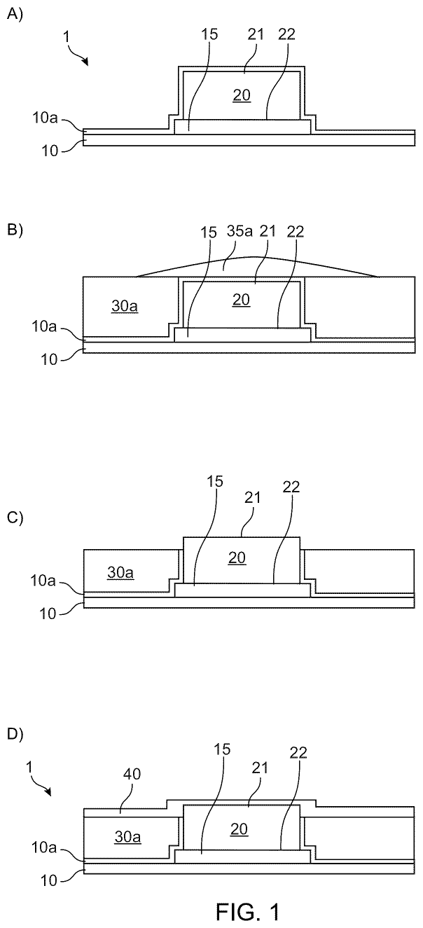

FIG. 1 illustrates an arrangement with an optoelectronic component and in particular a μLED. The μLED comprises a very small diameter of less than 70 μm or even smaller, for example, but not limited to less than 20 or even less than 10 μm. The optoelectronic component and μLED is implemented in FIG. 1A as a vertical optoelectronic component having a bottom surface 22 and top surface 21 opposite the bottom surface. The bottom and top surfaces comprise a respective contact area, which in the present case extends along the whole respective surface. The optoelectronic component 20 is arranged with its bottom surface 22 and its contact area on a respective contact plane 15, which is located on a carrier 10.

Contact plane 15 provides an electrical contact to the optoelectronic component and further connects to contact leads arranged within the carrier 10. Carrier 10 can be a substrate, a wafer structure or any other suitable rigid element, on which the optoelectronic components are arranged upon. A transparent dielectric material layer 10a is deposited on the surface of carrier 10 during subsequent processing steps. The dielectric material of layer 10a also covers the sidewalls as well as the top surface 21 of the optoelectronic component. The dielectric material 10a comprises SiO₂ or any other suitable material. It is sputtered on to the respective surface to provide a better wetting and contact of the spin-coated spin-on-glass material or dielectric material 30a, which is deposited on top of dielectric material layer 10a in a subsequent step.

The spinning process illustrated in FIG. 1B results in a protrusion 35a of some spin-coated material on top of the surface 21 of the optoelectronic component. The protrusion 35a is formed by the spin-on-glass material 30a being spinned upon, because the overall amount used for the spinning process is slightly larger than the actual available volume between the optoelectronic components on the carrier. Further, the spinning itself and other surface effects between the dielectric material 10a and the spin-on-glass material 30a? can result in some material being deposited on the top surface.

In any case, it is necessary to remove the redundant material from the top surface. For this purpose, a plasma etching process is performed which results in the structure depicted in FIG. 1C opening the top surface 21 of the optoelectronic component 10. However, the plasma etching process also removes portions of the material 30a adjacent to the optoelectronic component as well as portions of the dielectric material 10a. Since the etching rate of the dielectric material 10a is slower than the etching rate of the spin-on-glass material 30a, an edge or step between the optoelectronic component 20 and the dielectric material 10a as well as between dielectric material 10a and spin-on-glass material 30a will usually be formed.

Consequently, during the subsequent sputtering process of the conductive transparent layer using ITO for example, the adhesion between the spin-on-glass material and the conductive transparent material close to the edge portions of the optoelectronic component is reduced. This is partially also due to the exposed dielectric material, 10a, which may lead to a delamination between the three different materials, 30a, 10a and 40. Furthermore, the step in between the optoelectronic components 20 and the conductive transparent layer 40 may also cause a rupture or breaking in the conductive transparent layer 40, particularly since the used material is usually brittle and tends to easily break.

As a consequence thereof, embodiments provide a new planarization embedding material for an arrangement having a plurality of optoelectronic components which can be easier processed with a reduced risk of the delamination or rupturing of the transparent conductive layer material.

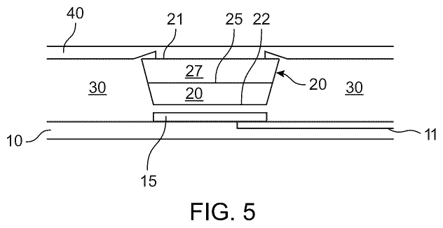

FIG. 5 illustrates a respective arrangement with an optoelectronic component embedded in such material. The μLED 20 comprises a layer stack having two differently doped layers 26 and 27 with an active region 25 arranged in between. The respective two differently doped layers 26 and 27 may comprise various current distribution and current transportation sublayers as well as cladding sublayers (not shown herein) adjacent to active region 25. Different semiconductor materials including a III-V semiconductor material like GaN, GaP or GaAs are suitable, although other material systems including ternary or quaternary systems like InGaN, AlGaN, AlGaP, InGaP, InAlGaN, InGaAIP or combinations thereof can be used. The optoelectronic component is implemented as a vertical μLED with two opposing surfaces 21 and 22, respectively, each of the surface comprising an electrical contact. In addition, surface 21 forming the top surface is a roughened to provide an improved light extraction.

The μLED 20 is arranged with its bottom surface 22 on a contact plane 15 arranged on the carrier substrate 10. Element 15 is connected to a contact line in an intermediate layer 11 arranged within the carrier substrate 10.

In accordance with the proposed principle, the optoelectronic component is embedded in an inactivated photo active material 30, which extends from the surface of carrier substrate 10 all the way to a level corresponding to the top surface 21 of the optoelectronic component. The expression “inactivated photo active material” or “inactive photo active material” refer to a photo active material, that is processed such that illumination of the material does not longer influence the material's characteristics.

A small portion of the inactivated photo active material 30 extends slightly onto the top surface around the edges of the optoelectronic component. The thickness of the additional material is small and may lie in the range of less than 1 μm and even less than 300 nm or even less than 100 nm. A conductive transparent layer 40 is deposited on top of the inactivated photo active material 30 and the top surface and contact area of the optoelectronic component. The thickness of that conductive transparent layer 40 is larger than the thickness of the protrusion 32 of the inactivated photo active material extending on the top surface. As a result, only a very small or no significant step is formed in the conductive transparent layer 40, thereby reducing the risk of rupture or delamination.

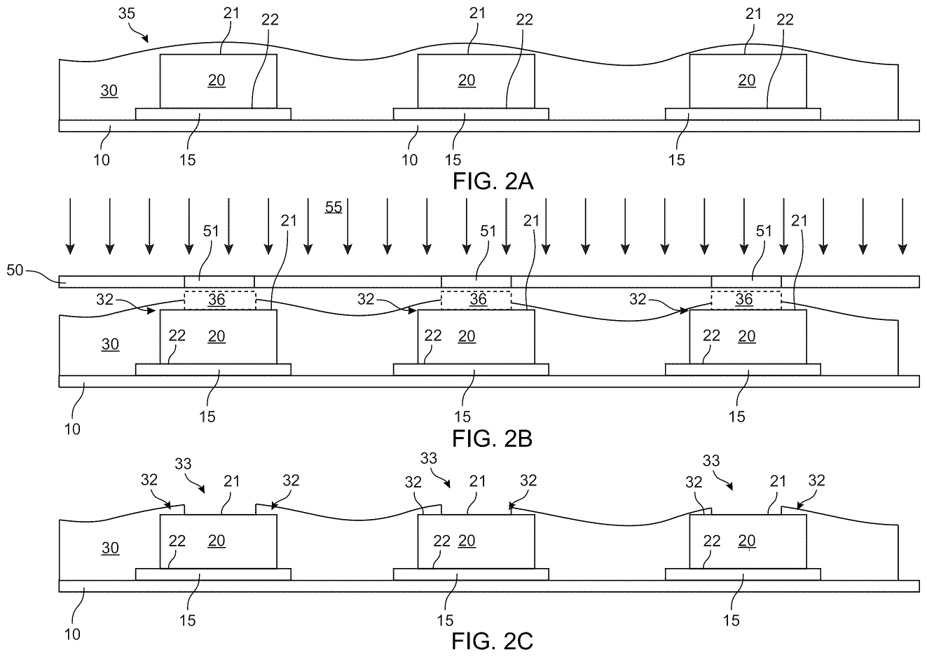

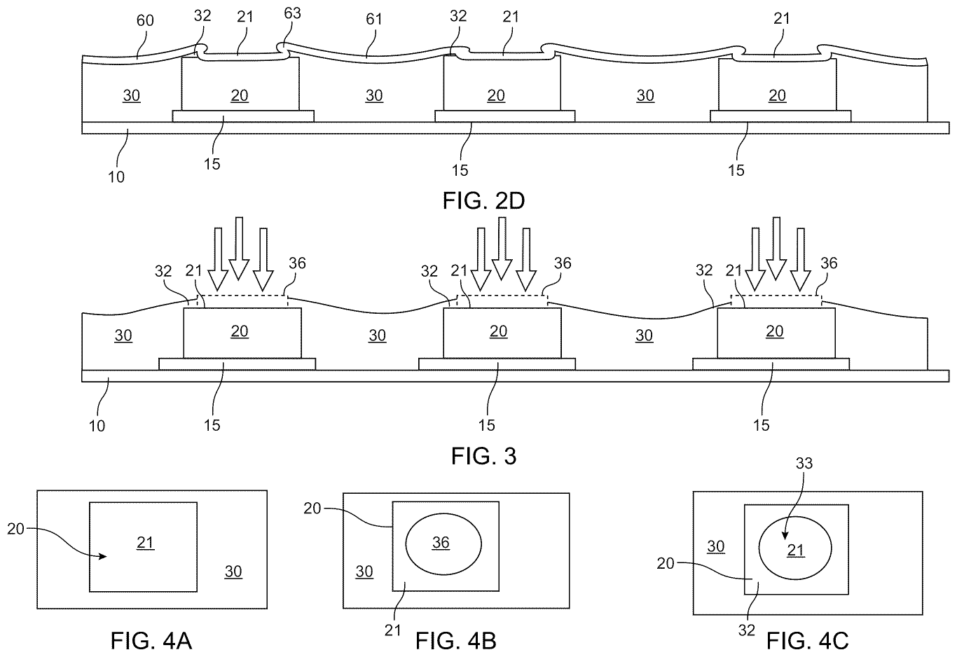

FIGS. 2A to 2D illustrate an embodiment of a method for processing an arrangement having a plurality of optoelectronic components. The method comprises the step of providing a carrier substrate 10 having a plurality of contact leads as well as contact elements 15 arranged in a certain structure on the surface of the carrier substrate. For example, the respective contact elements 15 can be placed in rows and columns with a predetermined distance between. Using various transfer processes, a plurality of optoelectronic components is attached on the respective contact elements 15 on the carrier substrate.

The bottom surface 22 of the optoelectronic components is slightly smaller than the respective contact elements 15 as illustrated in FIG. 2A, on which the optoelectronic components are placed upon. This allows to compensate for small tolerances or misalignments of the various components during the transfer process and ensures that the contact area on the bottom surface of each of the optoelectronic components is in electrical contact with the respective contact elements 15. Solder material is used to fix the bottom surface with contact area to the contact elements.

In a subsequent process step, a photo active material 30 is spinned onto the surface of the carrier substrate 10, as well as into the space between the optoelectronic components. The amount of photo active material used is adjusted such that the overall volume is slightly larger than the available volume so that portions of the photo active material form small protrusions 35 on top of the optoelectronic components 20. More particularly, those protrusions 35 are now resembling small hills following the position of the optoelectronic components and completely covering the top surfaces 21.

The photo active material is defined as a material which can simply be photo-structured without the need of additional etching steps to provide the structured layer thereof. A typical material can be MERCK Silicon-Organic-Glass found at https://www.merckgroup.com/research/science-space/presentations/2017-10-Micro-LED-Proposed-PPT-V3.pdf

In accordance with the proposed principle, a photo mask structure 50 is now arranged above the arrangement of optoelectronic components on the carrier substrate as depicted in FIG. 2B. The photo mask structure 50 comprises a plurality of transparent sections 51 like lenses or simply transparent windows, which are positioned opposite the top surfaces 21 of the respective optoelectronic components. The diameter of the respective transparent sections 51 are slightly smaller than the top surface 21 again to compensate for potential misalignment during the arrangement process of the optoelectronic components resulting in a slightly difference distances between adjacent devices. In addition, using a smaller dimension prevents to illuminate into the photo active material adjacent to the optoelectronic components, which could lead to removal of the developed photo-active material in between the components.

Nevertheless, the transparent sections 51 comprise a size sufficiently large to cover contact areas on the top surface 21, even during a small misalignment. The photo active material 30 is illuminated using light 55 with a specific wavelengths, thereby exposing and developing portions 36 of the photo active material opposite the transparent sections 51. As illustrated in FIG. 2B, the development results in developed photo active material 36 covering a portion of the top surfaces 21 but may leave edge portions 32 of the photo active material un-developed.

The developed portions are then removed using a simple removal process for the photo active material 30 like a solvent or a mild etching step. Removing the illuminated and developed portions 36 will provide a recess 33 and openings in the photo active material on the top surface 21 of the respective optoelectronic components shown in FIG. 2C. However, as illustrated small material portions 32 will remain on the circumferential edge of the optoelectronic components 20. The size of such material portions 32 is relatively small and the thickness may be in the range of a few 10 to a few 100 nm. In addition, due to the spinning process, these portions 32 may comprise a small curvature or an inclined surface, leading to an increasing thickness in the direction of the centre of the exposed top surface 21. Still it is noted in this regard that the curvature and thickness increase is significantly exceeded in the drawing.

In other words, the thickness of those material portions is small but may slightly vary and potentially increase from the edges towards the centre of the top surface 21. However, the overall height difference in the thickness of the photo active material between two adjacent devices (i.e. in the middle between two components) to the top of the surfaces 21 of those components is very small and may range between a few nanometres to approximately 400 nm. Usually, the height difference is less than the thickness of the conductive layer subsequently deposited onto the surface of the photo active material 30 and the top surfaces of the optoelectronic components. The resulting structure is presented in FIG. 2D.

A conductive transparent layer 60 comprises ITO and is sputtered onto the top surface of the photo active material 30 resulting in a substantially uniform thickness across the arrangement. The thickness is approximately 50 nm to 300 nm in areas 61 and 63 but can be smaller or larger depending on the overall size of the optoelectronic components as well as the thickness of the overlapping portions 32 on the top surface. However, the thickness is sufficiently small such that no step or edge is generated during the sputtering process. In this regard, FIG. 2D amplifies the overall height distance to illustrate the sputtering process.

The proposed principle allows to provide an arrangement comprising a plurality of optoelectronic components on a carrier substrate using a photo active material and a conductive transparent layer deposited thereupon. The photo active material does not delaminate from the sidewalls of the optoelectronic components due to thermal stress or mechanical stress and therefore provides a surface, on which the conductive transparent layer can be deposited. In addition, no significant step is generated between the sidewall edges of the optoelectronic components and the photo active material, which can cause a rupture or breaking of the conductive transparent layer. Rather, the conductive transparent layer can be deposited onto a smooth and planar surface of the photo active material and the top surfaces of the optoelectronic components. In some additional processing steps, the photo active material can be inactivated or otherwise processed to stabilize the material and render it resistant against oxygen or other gases or liquids.

In the present method of the structured photo mask layer was used to illuminate portions of the photo active layer and subsequently removing those from the optoelectronic components. However, this process can also be reversed, wherein the photo active material 30 between the optoelectronic components (that is above the carrier substrate) is illuminated and subsequently a non-illuminated material is removed from the top surface 21 of the optoelectronic components. The variation on this process step may be depending on the photo active material used and the subsequent stability after finishing the manufacturing and processing of the arrangement.

In addition, the photo mask layer can be subject to potential misalignment due to the fixed arrangement between the transparent sections 51 in regards to the position of the optoelectronic components on the carrier substrate.

Hence, it is suitable in some aspects to deviate from using a structured photo mask as shown in FIG. 2B. Rather, FIG. 3 illustrates an alternative embodiment, in which a direct laser imaging device is used to specifically illuminate portions of the photo active material 30.

More particularly, the exact position of the optoelectronic components 20 arranged on the carrier substrate 10 is captured in a previous step and particularly prior to spinning the photo active material on the carrier substrate. Possible misalignment of some of the optoelectronic components are identified. The evaluation of the respective positions for the optoelectronic components allows to realign the subsequent illumination process to ensure proper illumination of the portions 36 of the photo active material directly above the contact area. Hence, misalignment of the optoelectronic components during the arrangement step is compensated. After capturing and evaluating the position, a laser direct imaging device is used to illuminate the portions 36 of the photo active material as shown in FIG. 3. Again similar to the previous embodiment, small portions 32 of material 30 may remain unexposed covering the edges of the optoelectronic component.

FIGS. 4A to 4C illustrate a top view of the respective method steps in accordance with the proposed principle. In the embodiment, the optoelectronic component 20 is formed by a rectangular shape having a top surface 21, as depicted in FIG. 4A. The photo active material 30 surrounds the optoelectronic component 20 completely and also covers the top surface.

FIG. 4B illustrates the result of the illumination process of the photo active material using a photo mask structure (not shown herein), being positioned with its transparent portion 51 directly above the centre portion of the top surface 21 of the optoelectronic component 20. The transparent portion of the photo mask structure comprises an oval shape in this particular embodiment and is subsequently illuminated to develop the photo active material below.

The resulting developed photo active material portions 36 also comprises the oval shape and is subsequently removed to expose the top surface beneath. FIG. 4C illustrates the final result in which are small recess 33, exposing the top surface 21 of the optoelectronic component 20 is formed in the photo active material 30. Moreover, small circumferential portions 32 remain on the top surface of the optoelectronic component.

1.-16. (canceled)

17. A method for processing an arrangement with a plurality of vertical optoelectronic components, the method comprising:
providing the plurality of vertical optoelectronic components onto a carrier substrate, the plurality of vertical optoelectronic components comprising a contact area on a top surface opposite the carrier substrate;
embedding the plurality of vertical optoelectronic components into a photoactive material, the photoactive material covering spaces between adjacent optoelectronic components of the plurality of vertical optoelectronic components and the top surface;
illuminating portions of the photoactive material above the top surface comprising at least partially the contact area;
developing the photoactive material thereby removing portions of the photoactive material such that a portion of the top surface comprising at least partially the contact area is exposed and a portion of an inactivated photoactive material extending onto the top surface comprises a curvature and such that a thickness of the photoactive material partially increases towards an exposed contact are; and
providing a conductive transparent layer on the remaining photoactive material and the exposed portion of the top surface to electrically contact the contact area.

18. The method according to claim 17, wherein illuminating the portions comprises:
providing a structured mask layer onto the photoactive material such that a portion of the photoactive material above the top surface comprising at least partially the contact area is exposable to illumination; and
illuminating the exposed portions of the photoactive material.

19. The method according to claim 17, wherein illuminating the portions comprises:
providing a direct laser imaging device;
obtaining a position of the top surface of the plurality of optoelectronic components on the carrier substrate; and
illuminating, by the direct laser imaging device, portions of the photoactive material above the top surface comprising at least partially the contact area.

20. The method according to claim 17,
wherein developing comprises removing portions that have been illuminated such that not illuminated portions of the photoactive layer remain on the carrier substrate, or
wherein developing comprises removing portions that have not been illuminated such that illuminated portions of the photoactive material remain on the carrier substrate.

21. The method according to claim 18, wherein providing the structured mask layer comprises:
providing the structured mask layer comprising a plurality of transparent portions, and
arranging the structured mask layer above the photoactive material such that each transparent portion of the plurality of transparent portions is positioned above a respective portion of the top surface comprising at least partially the contact area, and
wherein an area of a transparent portion is smaller than an area of the top surface.

22. The method according to preceding claim 21, wherein each of the plurality of transparent portions comprises a shape of a circle, a rectangle, a polygon or an oval.

23. The method according to claim 17, wherein embedding the plurality of vertical optoelectronic components into the photoactive material comprises depositing the photoactive material such that photoactive material forms curved protrusions above locations of the plurality of vertical optoelectronic components, and wherein, optionally, a portion of the curved protrusions is left on the top surface after developing.

24. The method according to claim 17, wherein embedding the plurality of vertical optoelectronic components comprises:
spinning the photoactive material,
sputtering the photoactive material,
dispensing the photoactive material onto the top surface of the plurality of vertical optoelectronic components,
jetting the photoactive material onto the top surface of the plurality of vertical optoelectronic components, or
heat treating the photoactive material after developing.

25. The method according to claim 17, wherein developing comprises:
etching the illuminated portions of the photoactive material,
etching of non-illuminated portions of the photoactive material, and
backing the remaining photoactive material.

26. The method according to claim 17, wherein the conductive transparent layer comprises ITO and is sputtered onto the remaining photoactive material such that the conductive transparent layer extends over an edge between the photoactive material and exposed contact areas on the top surface.

27. An arrangement comprising:
a carrier substrate comprising a plurality of contact leads;
a plurality of vertical optoelectronic components arranged on the carrier substrate such that a first contact area of each of the plurality of vertical optoelectronic components connects a respective one of the plurality of contact leads, wherein each of the plurality of vertical optoelectronic components comprises a second contact area opposite the first contact area;
a non-conductive inactivated photoactive material arranged on the carrier substrate embedding the plurality of vertical optoelectronic components, wherein a portion of the inactivated photoactive material extends onto a top surface of a respective plurality of vertical optoelectronic components, leaving the second contact area partially exposed, and wherein the portion of the inactivated photoactive material extending onto the top surface comprises a curvature such that a thickness of the photoactive material partially increases towards an exposed second contact area; and
a transparent conductive layer covering the inactivated photoactive material and the exposed second contact area of the plurality of vertical optoelectronic components.

28. The arrangement according to claim 27, wherein the inactivated photoactive material comprises at least one of:
TiO₂,
SiO₂,
a siloxane filler material, or
graphite.

29. The arrangement according to claim 27, wherein the curvature comprises a curvature with an increasing slope towards the exposed second contact area when viewed in a cut view.

30. The arrangement according to claim 27, wherein an exposed area on the top surface comprises a shape of:
a circle,
a rectangle,
a polygon, or
an oval.

31. The arrangement according to claim 27, wherein the transparent conductive layer comprises a thickness that is larger than a step of the inactivated photoactive material extending above the top surface.

32. The arrangement according to claim 27, further comprising a dielectric layer arranged on portions of the carrier substrate and along sidewalls and the plurality of vertical optoelectronic components.
